(19) United States
(12) Patent Application Publication
(10) Pub. No.: US 2026/0082693 A1
(43) Pub. Date: Mar. 19, 2026

(54) High voltage semiconductor structure and manufacturing method thereof

(71) Applicant: UNITED MICROELECTRONICS CORP., Hsinchu City (TW)

(72) Inventor: Po-Yu Yang, Hsinchu City (TW)

(73) Assignee: UNITED MICROELECTRONICS CORP., Hsinchu City (TW)

(21) Appl. No.: 18/914,250

(22) Filed: Oct. 13, 2024

(30) Foreign Application Priority Data
Sep. 19, 2024 (TW) 113135381

(51) Int. Cl. H01L 27/092; H01L 21/8238; H01L 29/66

(52) U.S. Cl. CPC H10D 84/853; H10D 64/017; H10D 84/0188; H10D 84/0193; H10D 84/038

(57) ABSTRACT

The invention provides a high voltage semiconductor structure, which comprises a substrate, a fin structure located on the substrate, a gate structure located on the substrate and spanning the fin structure, and a first insulating structure and a second insulating structure spanning the fin structure and located in part of the fin structure, wherein the gate structure is located between the first insulating structure and the second insulating structure, and a top surface of the first insulating structure, a top surface of the second insulating structure and a top surface of the gate structure are aligned with each other.

### BACKGROUND OF THE INVENTION

### 1. Field of the Invention

The invention relates to the field of semiconductors, in particular to a high voltage semiconductor structure including a single diffusion break (SDB) and a manufacturing method thereof.

### 2. Description of the Prior Art

In recent years, as the size of field effect transistors (FETs) continues to shrink, the development of conventional planar FETs has faced the limit of manufacturing process. In order to overcome the process limitation, it has become the mainstream development trend to replace planar transistor devices with non-planar field effect transistor devices, such as fin field effect transistor (FinFET) devices. Because the three-dimensional structure of the fin field effect transistor device can increase the contact area between the gate and the fin structure, the control of the gate on the carrier channel region can be further increased, thereby reducing the drain-induced barrier lowering (DIBL) effect faced by small-sized devices and suppressing the short channel effect (SCE). Furthermore, because the finFET device will have a wider channel width under the same gate length, it can obtain double drain driving current. Even the threshold voltage of transistor elements can be adjusted by adjusting the work function of the gate.

However, there are still many limitations in the design of fin structure in the current FinFET device manufacturing process, which further affects the leakage current and overall electrical performance of the whole device. Therefore, how to improve the existing fin field effect transistor process is an important topic at present.

### SUMMARY OF THE INVENTION

The invention provides a high voltage semiconductor structure, which comprises a substrate, a fin structure located on the substrate, a gate structure located on the substrate and spanning the fin structure, and a first insulating structure and a second insulating structure spanning the fin structure and located in part of the fin structure, wherein the gate structure is located between the first insulating structure and the second insulating structure, and a top surface of the second insulating structure and a top surface of the gate structure are aligned with each other.

The invention also provides a method for manufacturing a high voltage semiconductor structure, which comprises providing a substrate, forming a fin structure on the substrate, forming a gate structure on the substrate and spanning the fin structure, and forming a first insulating structure and a second insulating structure spanning the fin structure and partially within the fin structure, wherein the gate structure is located between the first insulating structure and the second insulating structure, and a top surface of the first insulating structure, the second insulating structure and the gate structure are aligned with each other.

The invention is characterized by providing a semiconductor structure containing a single diffusion break and a manufacturing method thereof. In the invention, a plurality of sacrificial gate structures are firstly formed on the fin structure, and then when the sacrificial layer in the sacrificial gate structures is removed, a groove is simultaneously formed under the sacrificial gate structures, and then the groove is filled up with an insulating material layer to form a single diffusion break or an insulating structure, so that compared with the conventional single diffusion break process, the process of the invention is simpler, the structure is stable, and the problems of single diffusion break and gate structure displacement can be avoided. The semiconductor structure of the present invention can be applied to a general transistor or a high voltage transistor. When applied to a high voltage transistor, a part of the insulating structure is still used as a single diffusion break, and the other part of the insulating structure is used as an insulating structure between the source and the drain of the high voltage transistor, so that the current path can be prolonged and problems such as tunneling effect, voltage collapse and leakage current can be avoided under high operating voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIGS. 1 to 8 illustrate the steps of a method for forming a high voltage semiconductor structure in a first embodiment of the present invention, in which:

The top half of FIG. 1 and FIG. 8 is the top view of the high voltage semiconductor structure, and the bottom half is the schematic diagram of the cross-sectional structure.

FIGS. 2 to 7 show the schematic cross-sectional structure of the high voltage semiconductor structure.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

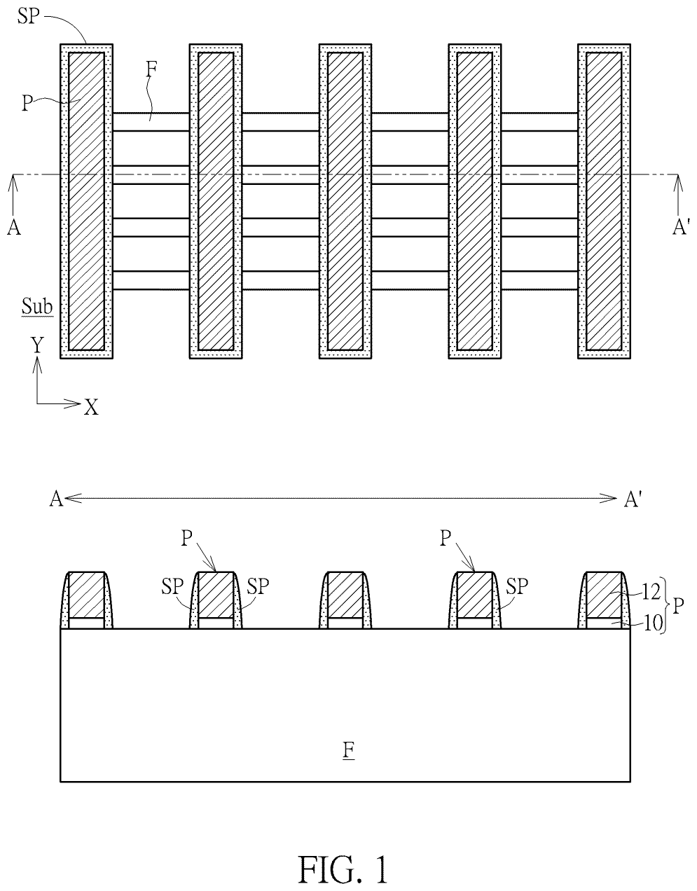

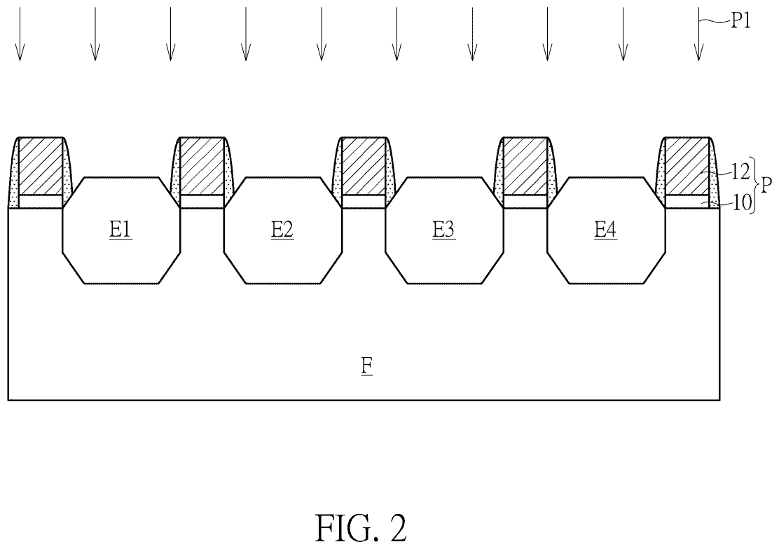

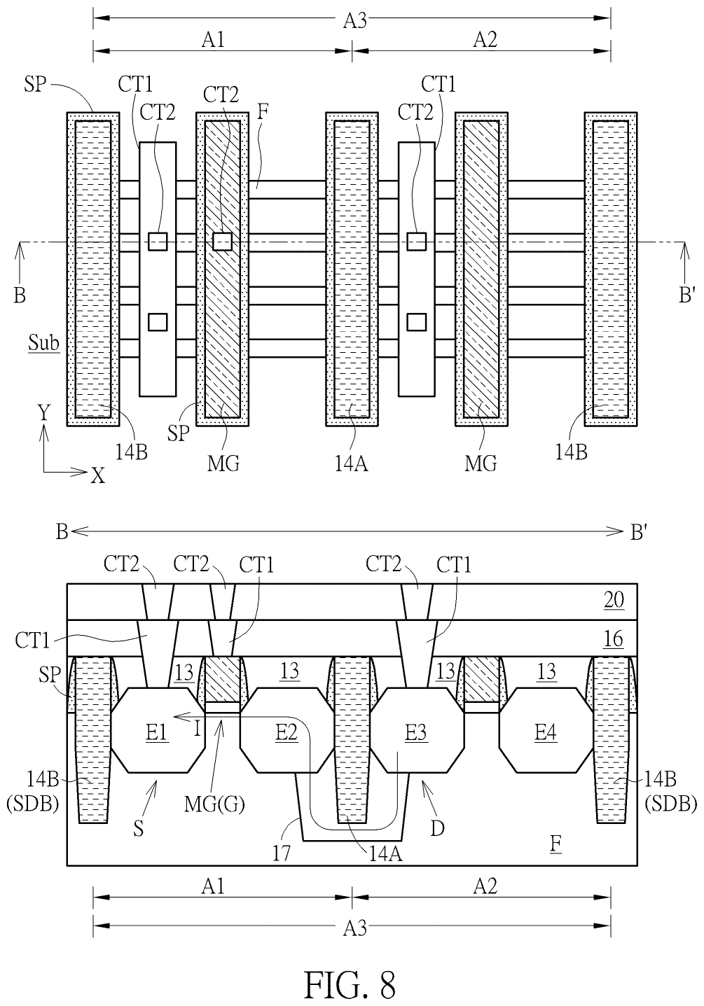

FIGS. 1 to 8 illustrate the steps of a method for forming a high voltage semiconductor structure in a first embodiment of the present invention. Among them, the top half of FIG. 1 and FIG. 8 is the top view of the high voltage semiconductor structure, and the bottom half is the schematic cross-sectional structure, while FIGS. 2 to 7 show the schematic cross-sectional structure of the high voltage semiconductor structure. First, please refer to the top view of FIG. 1 and the schematic cross-sectional structure taken along the section line A-A′. As shown in FIG. 1, a substrate (Sub) is provided. The substrate Sub is, for example, a semiconductor substrate such as a silicon substrate, a silicon-containing substrate or a silicon-on-insulator (SOI) substrate. The substrate Sub is formed with a plurality of fin structures F arranged along a first direction (for example, X direction). In the embodiment of bulk silicon, the formation method of the fin structures F is preferably by using a sidewall image transfer (SIT) technology, including forming a plurality of patterned sacrificial layers (not shown) on the substrate Sub through a photolithography and etching process, and sequentially performing deposition and etching processes, so as to form spacers (not shown) on the sidewall of each patterned sacrificial layer. Subsequently, the patterned sacrificial layer is removed, and an etching process is performed, so that the pattern of the spacer is transferred to the single-layer or multi-layer structure below, such as a composite structure consisting of a silicon oxide layer, a silicon nitride layer and a silicon oxide layer. Then, through an etching process, the pattern of the patterned mask is transferred to the lower substrate Sub to form a plurality of grooves and define the positions of the fin structures F at the same time. That is to say, the fin structure F protrudes from the surface of the substrate Sub, and the fin structure F and the substrate Sub contain the same material.

Then, a plurality of sacrificial gate structures P are formed on the substrate Sub, wherein the sacrificial gate structures P will be replaced by metal gates or structures such as single diffusion break (SDB) in the following steps. Here, the sacrificial gate structures P span each fin structure F and are arranged along the second direction (for example, the Y direction). In the manufacturing process, each sacrificial gate structure P includes a gate dielectric layer 10 and a sacrificial material layer 12, which are stacked together to form the sacrificial gate structure P. In addition, from the top view, the periphery of the sacrificial gate structure P also includes spacer SP surrounding the patterned sidewall of the sacrificial gate structure P. In the actual process, the gate dielectric layer 10 and the sacrificial material layer 12 can be respectively formed on the substrate Sub, for example, an oxide layer and a polysilicon layer are stacked on the substrate Sub and the fin structure F, and then the oxide layer and the polysilicon layer are etched by one or more patterning steps, leaving the oxide layer as the gate dielectric layer 10 and the polysilicon layer as the sacrificial material layer 12. Then, a deposition and etch back step is used to form the spacer SP on the patterned sidewall of the sacrificial gate structure P. In this embodiment, the material of the gate dielectric layer 10 is, for example, silicon oxide, the material of the sacrificial material layer 12 is, for example, polysilicon, and the material of the spacer SP is, for example, silicon nitride or silicon oxynitride, but the present invention is not limited to this.

As shown in FIG. 2, an epitaxial process P1 can then be performed to form a plurality of epitaxial layers in the substrate Sub on both sides of each sacrificial gate structure P. For convenience of explanation, each epitaxial layer is labeled as an epitaxial layer E1, an epitaxial layer E2, an epitaxial layer E3 and an epitaxial layer E4 respectively. As for the method of making the epitaxial layer, grooves (not shown) can be formed in the substrate Sub on both sides of the sacrificial gate structure P by etching process, and then the epitaxial layer can be formed in the grooves. According to different embodiments, the epitaxial layers E1-E4 may comprise a silicon germanium epitaxial layer suitable for a PMOS transistor, or the epitaxial layers E1-E4 may comprise a silicon carbon epitaxial layer suitable for an NMOS transistor. Then, an ion implantation process is performed to implant appropriate dopants, or appropriate dopants are simultaneously doped during the epitaxial process P1, so that the epitaxial layers E1-E4 can be used as a source/drain region. After the epitaxial layers E1-E4 are formed, a metal silicide process (not shown) may be performed to form a metal silicide in the source/drain, wherein the metal silicide process may include a pre-cleaning process, a metal deposition process, an annealing process, a selective etching process and a testing process. Besides, after the metal silicide process, other subsequent processes may be carried out.

In other embodiments of the present invention, the epitaxial process P1 shown in FIG. 2 may be omitted, and the source/drain regions may be directly formed by doping ions into the fin structure F. In these embodiments, both sides of the sacrificial gate structure P do not contain epitaxial layers E1-E4, but the fin structure F containing doped ions is used as the source/drain region. This variation is also within the scope of the present invention.

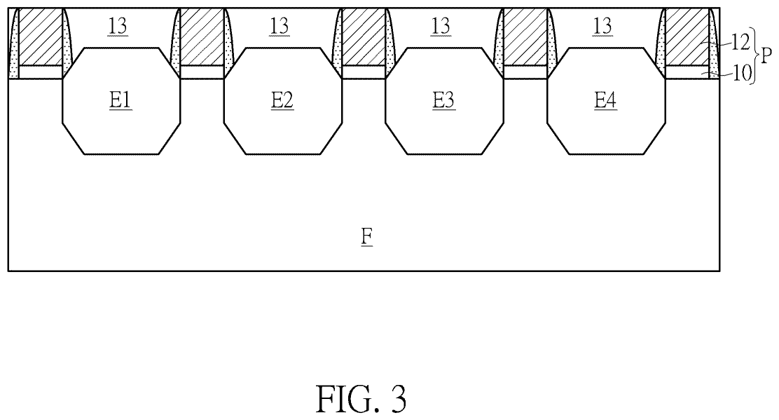

As shown in FIG. 3, a dielectric layer 13 is then formed to cover the substrate Sub, the fin structure F and the sacrificial gate structures P. And performing a planarization step, such as chemical mechanical polishing (CMP), so that the top surface of the sacrificial gate structure P is exposed, and preferably, the top surface of the sacrificial gate structure P is aligned with the top surface of the dielectric layer 13 at this time. In this embodiment, the material of the dielectric layer 13 is, for example, silicon oxide, silicon nitride, silicon oxynitride, etc., but not limited thereto. The method for forming the dielectric layer 13 includes, for example, a chemical vapor deposition (CVD) process, a physical vapor deposition (PVD) process, or an atomic layer deposition (ALD) process, but is not limited thereto.

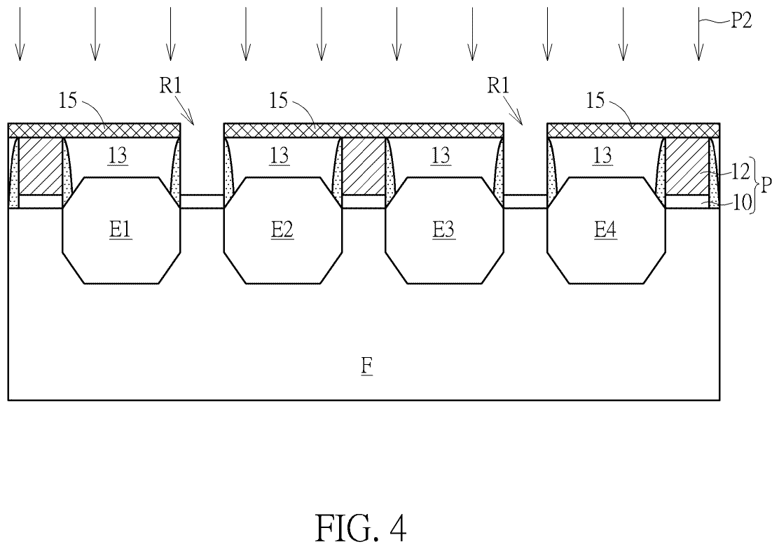

As shown in FIG. 4, an etching step P2 is performed to remove part of the sacrificial gate layer 12 in the sacrificial gate structure P. In more detail, a mask layer 15 can be formed to cover a part of the sacrificial gate structure P, and then an etching step P2 can be performed to remove the sacrificial gate layer 12 in the sacrificial gate structure P not covered by the mask layer 15. In addition, in some embodiments, except for removing the sacrificial gate layer 12 in the sacrificial gate structures P, the gate dielectric layers 10 in the sacrificial gate structures P can also be removed in the etching step P2. After the etching step P2, first grooves R1 are formed in the sacrificial gate structure P. It is worth noting that the sacrificial gate structures P from which the sacrificial gate layer 12 are removed in this step will be made into a gate structure (such as a metal gate) in the subsequent step, while the remaining sacrificial gate structures P will be made into an insulating structure or a single diffusion break (SDB) in the subsequent step. Preferably, in this step, the sacrificial gate structure P (or the first recesses R1) from which the sacrificial gate layer 12 has been removed and the sacrificial gate structure P from which the sacrificial gate layer 12 has not been removed are alternately arranged. That is, after the etching step P2, the first groove R1 and the sacrificial gate structure P are alternately arranged as viewed in the X direction. As shown in FIG. 4, the sacrificial gate structure P, the first groove R1, the sacrificial gate structure P, the first groove R1 and the sacrificial gate structure P are sequentially included from left to right.

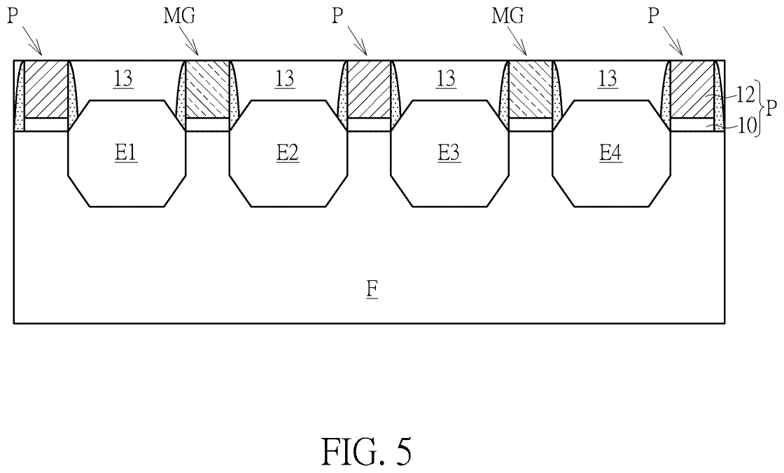

As shown in FIG. 5, multiple material layers are sequentially filled in each first groove R1 to form a metal gate in the first groove R1, and then the mask layer 15 and the multiple material layers outside the first groove R1 are removed. The above steps in FIG. 4 and FIG. 5 can be called replacement metal gate (RMG). In FIG. 5, a plurality of material layers, such as a high dielectric constant gate dielectric layer, a work function metal layer, a barrier layer, and a metal gate, can be sequentially formed in the first groove R1 to form a metal gate MG. Here, for the sake of simplicity, only the metal gate MG is used to represent the stacked structure of the multilayer material layers, but it can be understood that the metal gate MG may include a high-k (high dielectric constant) gate dielectric layer, a work function metal layer, a barrier layer, a gate and the above-mentioned spacer SP. In a preferred embodiment, the high dielectric constant gate dielectric layer can be a rare earth metal oxide layer or a lanthanide metal oxide layer, such as such as hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta2O₉, SBT), lead zirconate titanate (PbZrxTi₁-xO₃, PZT), barium strontium titanate (BaxSr₁-xTiO₃, BST) or a combination thereof, but not limited to the above. The work function metal layer and the barrier layer are formed by, for example, physical vapor deposition (PVD), and the work function metal layer can be a P-type work function metal layer, such as nitrides of nickel (Ni), tungsten (W), molybdenum (Mo), tantalum (Ta) and titanium (Ti), or an N-type work function metal layer, such as titanium aluminides (TiAl), zirconium aluminide (ZrAl), aluminum tungsten (WAl), aluminum tantalum (TaAl) or hafnium aluminum (HfAl), and the barrier layer is, for example, titanium/titanium nitride (Ti/TiN) or tantalum/tantalum nitride (Ta/TaN), but is not limited to the above. It should be easily understood by those skilled in the art that the formation mode and material of the metal gate MG of the present invention are not limited to the foregoing.

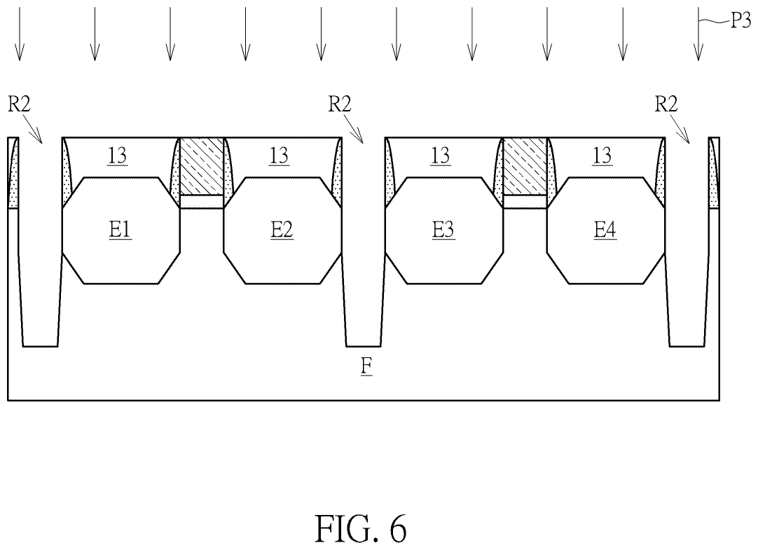

Next, as shown in FIG. 6, an etching step P3 is performed to remove the sacrificial gate layer 12 and the gate dielectric layer 10 of the remaining sacrificial gate structures P, and remove part of the fin structures F under the sacrificial gate structures P to form a plurality of second grooves R2. In more detail, the etching step P3 here may include a plurality of etching steps, which sequentially remove the sacrificial gate layer 12 and the gate dielectric layer 10 of the sacrificial gate structure P, and then continue to remove part of the fin structure F below, and form a plurality of second grooves R2 in the fin structure F. Preferably, the bottom surface of the second groove R2 is lower than that of the epitaxial layers E1-E4, but the present invention is not limited to this. In addition, it is preferable that the second groove R2 has vertical side walls and uniform width, that is to say, the width of the top surface, the width of the bottom surface and the width of the middle part of the second groove R2 are measured, and it is preferable that the widths of the above places are the same. But the present invention is not limited thereto.

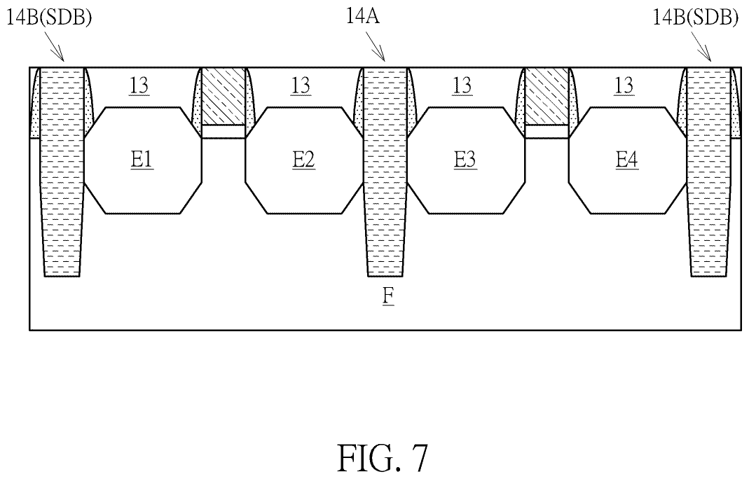

As shown in FIG. 7, an insulating material layer is then filled in each second groove R2, and then the redundant insulating material layer is removed to form a first insulating structure 14A and a second insulating structure 14B in the second groove R2, wherein the top surfaces of the first insulating structure 14A and the second insulating structure 14B are aligned with the top surface of the dielectric layer 13. It should be noted that since the second groove R2 preferably has a uniform width, the first insulating structure 14A and the second insulating structure 14B here also have a uniform width. In other words, the width of the top surface, the width of the bottom surface and the width of the middle part of the first insulating structure 14A or the second insulating structure 14B are preferably the same, but the present invention is not limited to this. In this embodiment, the materials of the first insulating structure 14A and the second insulating structure 14B are, for example, silicon oxide, silicon nitride or silicon oxynitride, but not limited thereto. In addition, it is preferable that the first insulating structure 14A and the second insulating structure 14B are made of single-layer materials, that is, only single-layer structures are contained in the second groove R2, and the first insulating structure 14A and the second insulating structure 14B are made of the same insulating material.

Finally, as shown in FIG. 8, dielectric layer 16 and dielectric layer 20 are formed, and contact structures CT1 and CT2 are formed in dielectric layer 16 and dielectric layer 20. In this embodiment, the materials of the dielectric layer 16 and the dielectric layer 20 are, for example, silicon oxide, but not limited thereto. The materials of the contact structures CT1 and CT2 are, for example, metals with good conductivity such as tungsten, cobalt, copper, aluminum, gold, silver, etc., but are not limited thereto. Preferably, the contact structure CT1 connects each epitaxial layer E1-E4 (source/drain) and part of the metal gate MG, while the contact structure CT2 connects part of the contact structure CT1.

One of the characteristics of the present invention is that the first insulating structure 14A and the second insulating structure 14B can be used as a single diffusion break (SDB) of a semiconductor structure, or as an insulating layer between the source and the drain in a high voltage transistor, so as to lengthen the current path between the source and the drain and avoid the leakage current of the device caused by a large electric field. In more detail, as shown in FIG. 8, the first insulating structure 14A and the second insulating structure 14B here can be regarded as a single diffusion break (SDB) of the semiconductor structure, that is, another adjacent semiconductor structure can be included on the other side (not shown) of the single diffusion break (SDB), so setting the single diffusion break (SDB) can reduce the gap between adjacent semiconductor elements and improve the element density.

For example, in some embodiments, both the first insulating structure 14A and the second insulating structure 14B can be regarded as a single diffusion break SDB. For example, in FIG. 8, an area A1 and an area A2 are defined, wherein the area A1 contains a metal gate MG and two epitaxial layers E1 and E2 (source and drain) located next to the metal gate MG, and these elements are located between the first insulating structure 14A and the second insulating structure 14B on the left. At this time, the epitaxial layers E1 and E2 (source and drain) next to the metal gate MG can be regarded as a transistor cell, and the first insulating structure 14A and the second insulating structure 14B on the left side can be regarded as single diffusion break on both sides of the transistor cell respectively. Similarly, the area A2 also contains another transistor cell, including a metal gate MG and epitaxial layers E3 and E4, and the first insulating structure 14A and the second insulating structure 14B on the right side are used as single diffusion breaks on both sides of this transistor cell. Therefore, the transistor cells in the area A1 and the transistor cells in the area A2 are separated from each other by the first insulating structure 14A, so that the device can be closely arranged and the density of the device can be improved.

In other embodiments, two adjacent regions can also be merged and applied to high voltage transistors. Among them, the main difference between the high voltage transistor and the above-mentioned general transistor is that the applied voltage is higher (usually above 10 volts, but not limited to this), so a strong electric field will be generated between the source and drain of the high voltage transistor. Usually, in order to reduce the tunneling effect and leakage current caused by excessive current, an insulating layer can be set between the source and the drain of the high voltage transistor to block part of the current, so as to prolong the current path and avoid the tunneling effect. Therefore, as shown in FIG. 8, an area A3 can be defined as the smallest cell of a high voltage transistor, wherein the area A3 is composed of the area A1 and the adjacent area A2. At this time, the first insulating structure 14A in the area A3 is not used as a single diffusion break in the area A3, but as an insulating layer between the source and the drain in the high voltage transistor. More specifically, the metal gate MG on the left side of the first insulating structure 14A can be connected to the gate terminal G, the epitaxial layer E1 on the left side of the metal gate MG can be connected to the source terminal S, and the epitaxial layer E3 on the right side of the insulating layer can be connected to the drain terminal D. As for the other epitaxial layers E2 and E4, they can remain floating, that is, they are not connected to the voltage source. In this way, the smallest cell of a high voltage transistor can be formed in the area A3 of FIG. 8. When the gate terminal G is turned on, the channel under the metal gate MG is also turned on, and the current can flow from the drain terminal D to the source terminal S, in which the current path I is drawn in FIG. 8. It can be seen from the figure that the current path must pass from below the first insulating structure 14A to the source terminal S, so the current path can be increased to avoid tunneling effect and leakage current. It is worth noting that, in order to make the current path flow smoothly in the substrate S, when the semiconductor structure is applied to the high voltage semiconductor, a drift region 17 can be additionally formed below the first insulating structure 14A, which has the same conductivity type as the epitaxial layer E2 and the epitaxial layer E3, for example, and the drift region 17 can create a current path for the current to pass through the first insulating structure 14A. It is worth noting that if the semiconductor structure of the present invention should not be used for high voltage transistors, it is unnecessary to form the drift region 17.

Therefore, from the above description, it can be seen that the structure proposed in FIG. 8 of the present invention can be applied to general transistors or high voltage transistors depending on the connection mode of each element. When the structure of the present invention is applied to a high voltage transistor, the source terminal S and the drain terminal D are located on both sides of the first insulating structure 14A, so as to extend the current path through the first insulating structure 14A.

When the semiconductor structure of the present invention is applied to a high voltage transistor, please refer to area A3, in which the smallest cell of a high voltage transistor contains two metal gates MG and four epitaxial layers E1-E4, wherein one metal gate MG is connected to the gate terminal G, and the other two epitaxial layers E1 and E3 located on both sides of the first insulating structure 14A are connected to the source terminal S and the drain terminal D, and the remaining metal gate MG and two epitaxial layers E2 and E4 can float. With regard to the floating connection described here, it can be understood that the epitaxial layers E2 and E4 are not connected to the signal source. Or from the structural point of view, the contact structure CT1 may not be formed above the metal gate MG, the epitaxial layer E2 and the epitaxial layer E4, but the contact structure CT1 may be formed above the epitaxial layer E1 and the epitaxial layer E3. Therefore, the dielectric layer 16 covers the complete top surface of the metal gate MG, and the dielectric layer 13 covers the complete top surfaces of the epitaxial layers E2 and E4, but the dielectric layer 13 only covers part of the top surfaces of the epitaxial layers E1 and E3 (because a contact structure CT1 are formed on the top surfaces of the epitaxial layers E1 and E3).

Another feature of the present invention is that the position of the sacrificial gate is defined first, and then the single diffusion break SDB is formed. Different from the general process, a single diffusion break SDB is usually formed in the fin structure F first, and then a dummy gate structure is continuously formed above the single diffusion break SDB. The process sequence of the invention is different from that of the prior art. Because the position of the sacrificial gate structure P is defined first, and the subsequent single diffusion break SDB is directly formed under the original sacrificial gate structure P, please refer to FIG. 6 and FIG. 7 together. Because the position of the second groove R2 corresponds to the position of the original sacrificial gate structure P, the formation position of the single diffusion break SDB can be better controlled, and the problem that the single diffusion break may deviate from the position of the dummy gate structure in the prior art will not occur.

In addition, the first insulating structure 14A and the second insulating structure 14B of the present invention are formed in the same process as the single diffusion break SDB, and are preferably composed of a single layer of insulating material, so the present invention also has the advantages of simple process and stable structure.

Based on the above description and drawings, a high voltage semiconductor structure of the present invention includes a substrate Sub, a fin structure F located on the substrate Sub, a gate structure (i.e., the metal gate MG) located on the substrate Sub and spanning the fin structure F, and a first insulating structure 14A and a second insulating structure 14B spanning the fin structure and located in part of the fin structure F. The gate structure MG is located between the first insulating structure 14A and the second insulating structure 14B, wherein a top surface of the first insulating structure 14A, a top surface of the second insulating structure 14B and a top surface of the gate structure MG are aligned with each other.

In some embodiments of the present invention, the second insulating structure 14B is a single diffusion break (SDB).

In some embodiments of the present invention, a first doped region (e.g., the epitaxial layer E1 in the figure) and a second doped region (e.g., the epitaxial layer E2 in the figure) are located in the fin structure F and at both sides of the gate structure MG, wherein the first doped region E1 and the second doped region E2 are located between the first insulating structure 14A and the second insulating structure 14B.

In some embodiments of the present invention, a third doped region (for example, the epitaxial layer E3 in the figure) is located in the fin structure F, wherein the first insulating structure 14A is located between the first doped region E1 and the third doped region E3.

In some embodiments of the present invention, the first doped region E1 is connected to a source terminal S, the third doped region E3 is connected to a drain terminal D, and the second doped region E2 is in a floating state.

In some embodiments of the present invention, a metal connection layer (i.e., the contact structure CT1 and the contact structure CT2) is further included, which electrically connects the first doped region E1 and the third doped region E3, but does not connect the second doped region E2.

In some embodiments of the present invention, both the first insulating structure 14A and the second insulating structure 14B are composed of a single insulating layer.

In some embodiments of the present invention, a bottom width of the first insulating structure 14A is equal to a top width of the first insulating structure 14A.

In some embodiments of the present invention, a plurality of spacers SP are located on the fin structure F, and the plurality of spacers SP are located on both sidewalls of the gate structure MG and on part of the sidewalls of the first insulating structure 14A and the second insulating structure 14B (as shown in Figure, the spacers SP are left on the sidewalls of the first insulating structure 14A and the second insulating structure 14B because the first insulating structure 14A and the second insulating structure 14B are formed first).

The invention also provides a method for manufacturing a high voltage semiconductor structure, which comprises providing a substrate Sub, forming a fin structure F on the substrate Sub, forming a gate structure MG on the substrate Sub and spanning the fin structure F, and forming a first insulating structure 14A and a second insulating structure 14B spanning the fin structure F and located in part of the fin structure F, wherein the gate structure MG is located between the first insulating structure 14A and the second insulating structure 14B, wherein a top surface of the first insulating structure 14A, a top surface of the second insulating structure 14B and a top surface of the gate structure MG are aligned with each other.

In some embodiments of the present invention, the second insulating structure 14B is a single diffusion break (SDB).

In some embodiments of the present invention, a first doped region (e.g., the epitaxial layer E1, but it can also be a substrate doped region) and a second doped region (e.g., the epitaxial layer E2, but it can also be a substrate doped region) are formed in the fin structure F and located at both sides of the gate structure MG, wherein the first doped region E1 and the second doped region E2 are located between the first insulating structure 14A and the second insulating structure 14B.

In some embodiments of the present invention, a third doped region E3 is formed in the fin structure F, wherein the first insulating structure 14A is located between the first doped region E1 and the third doped region E3.

In some embodiments of the present invention, the first doped region E1, the second doped region E2 and the third doped region E3 respectively comprise an epitaxial layer.

In some embodiments of the present invention, the first doped region E1 is connected to a source terminal S, the third doped region is connected to a drain terminal D, and the second doped region E2 is in a floating state.

In some embodiments of the present invention, a metal connection layer (i.e., the contact structure CT1 and the contact structure CT2) is formed to electrically connect the first doped region E1 and the third doped region E3, but the metal connection layer does not electrically connect the second doped region E2.

In some embodiments of the present invention, both the first insulating structure 14A and the second insulating structure 14B are composed of a single insulating layer.

In some embodiments of the present invention, a bottom width of the first insulating structure 14A is equal to a top width of the first insulating structure 14A.

In some embodiments of the present invention, the step of forming the first insulating structure 14A and the second insulating structure 14B further comprises: forming a gate structure MG, a first sacrificial gate structure P and a second sacrificial gate structure P on the fin structure F, wherein the first sacrificial gate structure P and the second sacrificial gate structure P are located at two sides of the gate structure MG respectively, forming a plurality of spacer SP, the plurality of spacer SP are respectively located on the two sidewalls of the gate structure MG and the two sidewalls of the first sacrificial gate structure P and the second sacrificial gate structure P, and an etching step is performed to remove a sacrificial material layer 12 of the first sacrificial gate structure P and the second sacrificial gate structure P, and in the etching step, a plurality of grooves R2 are respectively formed in fin structures below the first sacrificial gate structure P and the second sacrificial gate structure P.

In some embodiments of the present invention, it further includes filling an insulating material layer into each groove R2 and filling up each groove R2, wherein a top surface of the insulating material layer is flush with a top surface of the spacer SP, and the insulating material layer filling each groove R2 is defined as a first insulating structure 14A and a second insulating structure 14B, respectively.

To sum up, the invention is characterized by providing a semiconductor structure containing a single diffusion break and a manufacturing method thereof. In the invention, a plurality of sacrificial gate structures are firstly formed on the fin structure, and then when the sacrificial layer in the sacrificial gate structures is removed, a groove is simultaneously formed under the sacrificial gate structures, and then the groove is filled up with an insulating material layer to form a single diffusion break or an insulating structure, so that compared with the conventional single diffusion break process, the process of the invention is simpler, the structure is stable, and the problems of single diffusion break and gate structure displacement can be avoided. The semiconductor structure of the present invention can be applied to a general transistor or a high voltage transistor. When applied to a high voltage transistor, a part of the insulating structure is still used as a single diffusion break, and the other part of the insulating structure is used as an insulating structure between the source and the drain of the high voltage transistor, so that the current path can be prolonged and problems such as tunneling effect, voltage collapse and leakage current can be avoided under high operating voltage.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A high voltage semiconductor structure comprising:
a substrate, a fin structure is located thereon;
a gate structure located on the substrate and spans the fin structure; and
a first insulating structure and a second insulating structure span the fin structure and are located in part of the fin structure, and the gate structure is located between the first insulating structure and the second insulating structure, wherein a top surface of the first insulating structure, a top surface of the second insulating structure and a top surface of the gate structure are aligned with each other.

2. The high voltage semiconductor structure according to claim 1, wherein the second insulating structure is a single diffusion break (SDB).

3. The high voltage semiconductor structure according to claim 1, further comprising a first doped region and a second doped region located in the fin structure and at both sides of the gate structure, wherein the first doped region and the second doped area Are located between the first insulating structure and the second insulating structure.

4. The high voltage semiconductor structure according to claim 3, further comprising a third doped region located in the fin structure, wherein the first insulating structure is located between the first doped region and the third doped region.

5. The high voltage semiconductor structure according to claim 4, wherein the first doped region is connected to a source terminal, the third doped region is connected to a drain terminal, and the second doped region is in a floating state.

6. The high voltage semiconductor structure according to claim 5, further comprising a metal connection layer electrically connecting the first doped region and the third doped region, but the metal connection layer does not electrically connect the second doped region.

7. The high voltage semiconductor structure according to claim 1, wherein both the first insulating structure and the second insulating structure are composed of a single insulating layer.

8. The high voltage semiconductor structure according to claim 1, wherein a bottom width of the first insulating structure is equal to a top width of the first insulating structure.

9. The high voltage semiconductor structure according to claim 1, further comprising a plurality of spacers located on the fin structure, and the spacers are located on both sidewalls of the gate structure and part of the sidewalls of the first insulating structure and the second insulating structure.

10. A manufacturing method of a high voltage semiconductor structure, comprising:
providing a substrate;
forming a fin structure on the substrate;
forming a gate structure on the substrate and spanning the fin structure; and
forming a first insulating structure and a second insulating structure spanning the fin structure and located in part of the fin structure, wherein the gate structure is located between the first insulating structure and the second insulating structure, and a top surface of the first insulating structure, the second insulating structure and the gate structure are aligned with each other.

11. The method for manufacturing a high voltage semiconductor structure according to claim 10, wherein the second insulating structure is a single diffusion break (SDB).

12. The manufacturing method of the high voltage semiconductor structure according to claim 10, further comprising forming a first doped region and a second doped region located in the fin structure and at both sides of the gate structure, wherein the first doped region and the second doped region are located between the first insulating structure and the second insulating structure.

13. The method for manufacturing a high voltage semiconductor structure according to claim 12, further comprising forming a third doped region in the fin structure, wherein the first insulating structure is located between the first doped region and the third doped region.

14. The method for manufacturing a high voltage semiconductor structure according to claim 13, wherein the first doped region, the second doped region and the third doped region respectively comprise an epitaxial layer.

15. The method for manufacturing a high voltage semiconductor structure according to claim 13, wherein the first doped region is connected to a source terminal, the third doped region is connected to a drain terminal, and the second doped region is in a floating state.

16. The method for manufacturing a high voltage semiconductor structure according to claim 15, further comprising forming a metal connection layer to electrically connect the first doped region and the third doped region, but the metal connection layer does not electrically connect the second doped region.

17. The method for manufacturing a high voltage semiconductor structure according to claim 10, wherein both the first insulating structure and the second insulating structure are composed of single insulating layer.

18. The method for manufacturing a high voltage semiconductor structure according to claim 10, wherein a bottom width of the first insulating structure is equal to a top width of the first insulating structure.

19. The method for manufacturing a high voltage semiconductor structure according to claim 10, wherein the step of forming the first insulating structure and the second insulating structure further comprising:
forming the gate structure, a first sacrificial gate structure and a second sacrificial gate structure on the fin structure, wherein the first sacrificial gate structure and the second sacrificial gate structure are located at two sides of the gate structure respectively;
forming a plurality of spacers, wherein the spacers are respectively located on two side walls of the gate structure and on two side walls of the first sacrificial gate structure and the second sacrificial gate structure; and
performing an etching step to remove a sacrificial layer of the first sacrificial gate structure and the second sacrificial gate structure, and simultaneously forming a plurality of grooves in the fin structure below the first sacrificial gate structure and the second sacrificial gate structure in the etching step.

20. The method for manufacturing a high voltage semiconductor structure according to claim 19, further comprising filling an insulating material layer into each groove and filling up each groove, wherein a top surface of the insulating material layer is aligned with a top surface of the spacer, and the insulating material layer filling each groove is defined as the first insulating structure and the second insulating structure respectively.
